(19) United States
(12) Patent Application Publication
(10) Pub. No.: US 2014/0110741 A1
(43) Pub. Date: Apr. 24, 2014

(54) LIGHT-EMITTING DEVICE

(71) Applicant: EPISTAR CORPORATION, Hsinchu (TW)

(72) Inventors: Chen Ou, Hsinchu city (TW); Chun-Wei Chang, Hsinchu city (TW); Chih-Wei Wu, Hsinchu city (TW)

(21) Appl. No.: 13/654,486

(22) Filed: Oct. 18, 2012

(51) Int. Cl. H01L 33/36

(52) U.S. Cl. CPC H01L 33/36
USPC 257/99

(57) ABSTRACT

A light-emitting device, includes: a substrate; a light-emitting structure formed on the substrate and including a first portion, and a second portion where no optoelectronic conversion occurs therein; and a first electrode located on both the first portion and the second portion.

### TECHNICAL FIELD

The application relates to a light-emitting device, in particular, regarding to a light-emitting device having high electrical efficiency.

### DESCRIPTION OF BACKGROUND ART

The current-spreading effect of an LED device regards the brightness thereof. Conventionally, an electrode pad can be formed on the top semiconductor layer to input current to an LED device, and one or more than one extension electrodes extended from the electrode pad can be also formed on the top semiconductor layer to improve current-spreading.

On one hand, the disposition of the extension electrodes causes adverse influence on the light-extraction of the LED device because the extension electrodes are metal which can absorb or block the light of the LED device. On the other hand, if the contact area between the extension electrode and the top semiconductor layer is insufficient, the forward voltage of the LED device may raise so the electrical efficiency is lowered.

In addition, the light emitting device can be further connected to other components in order to form a light emitting apparatus. The light-emitting device may be mounted onto a submount with the side of the substrate, or a solder bump or a glue material may be formed between the submount and the light-emitting device, therefore a light-emitting apparatus is formed. Besides, the submount further comprises the circuit layout electrically connected to the electrode of the light-emitting device via an electrical conductive structure such as a metal wire.

### SUMMARY OF THE DISCLOSURE

A light-emitting device, includes: a substrate; a light-emitting structure formed on the substrate and comprising a first portion, and a second portion where no optoelectronic conversion occurs therein; and a first electrode located on both the first portion and the second portion.

A light-emitting device, includes: a single-crystalline substrate; a light-emitting structure formed on the substrate and comprising a first portion and a second portion, wherein the first portion comprises part of a lower semiconductor layer, an active layer on the lower semiconductor layer and an upper semiconductor layer on the active layer, and no optoelectronic conversion occurs in the second portion; and a first electrode electrically connected to the upper semiconductor layer and entirely located outside the first portion.

### BRIEF DESCRIPTION OF THE DRAWINGS

FIGS. 1A to 1D show a light-emitting device in accordance with a first embodiment of the present application.

FIGS. 2A to 2C show a light-emitting device in accordance with a second embodiment of the present application.

FIG. 3 shows a light-emitting device in accordance with a third embodiment of the present application.

FIG. 4 shows a light-emitting device in accordance with a fourth embodiment of the present application.

### DETAILED DESCRIPTION OF PREFERRED EMBODIMENTS

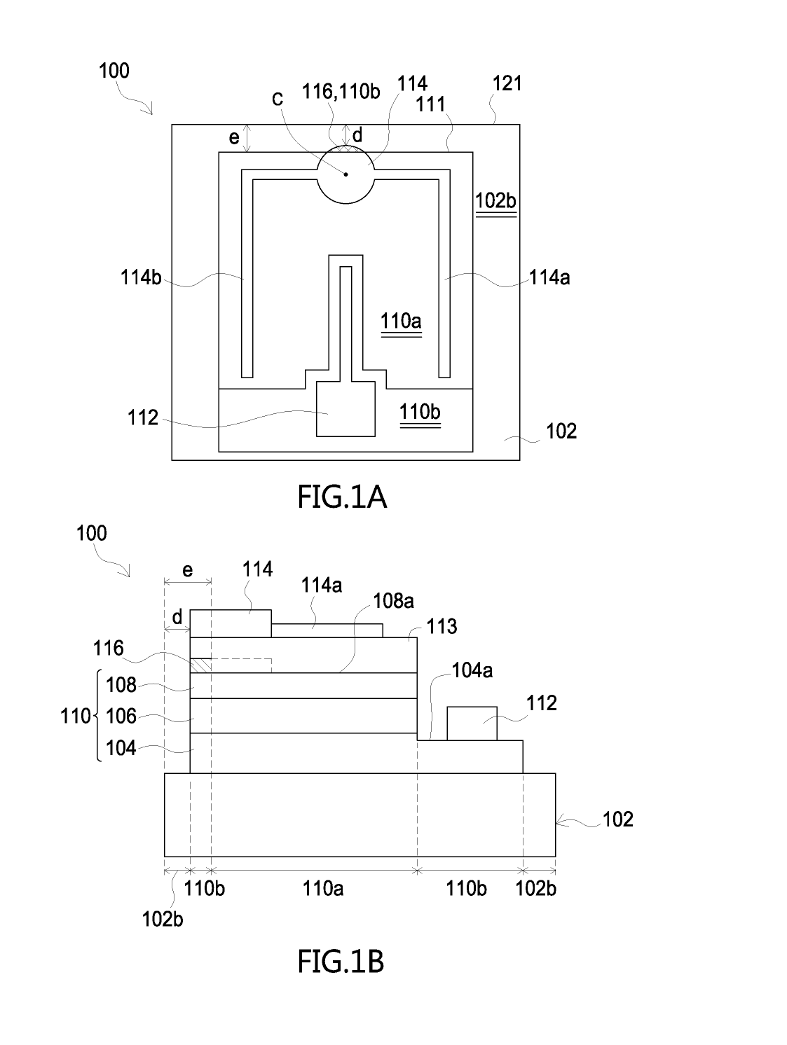

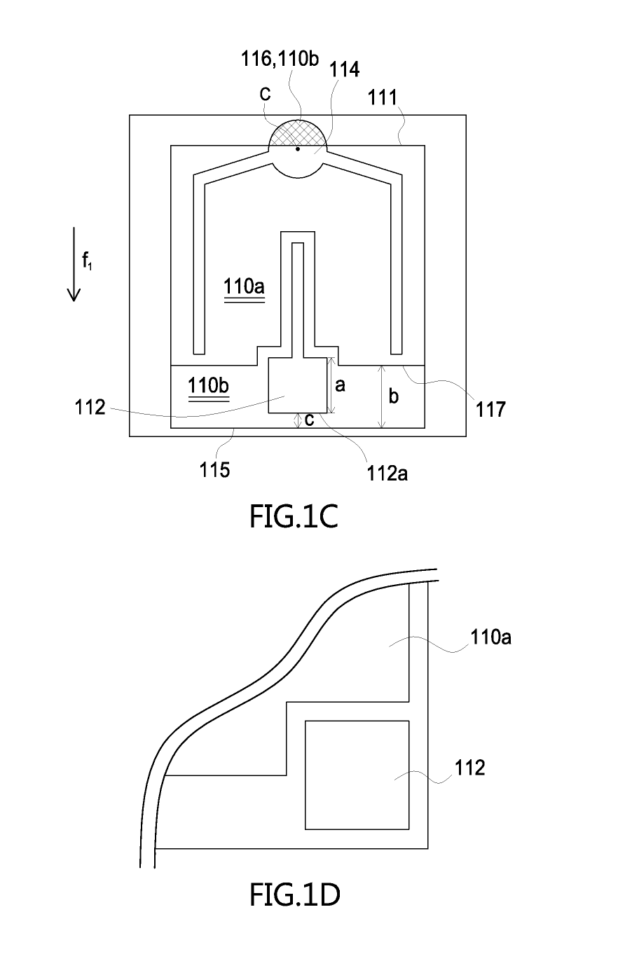

Referring to FIGS. 1A and 1B, a light-emitting device in accordance with a first embodiment of the present application is disclosed. A light-emitting device 100 includes: a substrate 102, for example, an insulative and single-crystalline substrate, and in the embodiment the substrate 102 can be Sapphire; a light-emitting structure 110 formed on the substrate 102, including a lower semiconductor layer 104, an active layer 106 and an upper semiconductor layer 108; a first electrode 114 electrically connected to the upper semiconductor layer 108; and a second electrode 112 formed on the lower semiconductor layer 104. There are two portions defined in the light-emitting structure 110: a first portion 110a having a first top face 108a and a second portion 110b where no optoelectronic conversion occurs therein. The first portion 110a includes part of the upper semiconductor layer 108 having the first top face 108a, the active layer 106, and the lower semiconductor layer 104. In the embodiment, the ratio of the area of the first portion 110a of the light-emitting structure 110 to the area of the substrate 102 can be 0.5 to 0.8. The second portion 110b can include part of the lower semiconductor layer 104 having a second top face 104a. The second portion 110b can also include a region under the first electrode 114 by disposing a current blocking portion 116 between the first electrode 114 and the upper semiconductor layer 108 as disclosed in the embodiment.

The substrate 102 can include an exposed region 102b other than the area having the light-emitting structure 110 disposed thereon. To be more specific, the exposed region 102b can surround the area having the light-emitting structure 110 disposed thereon. Furthermore, the area of the current blocking portion 116 can be smaller than that of the first electrode 114 as indicated by the stripe area in solid line in FIG. 1B, or the current blocking portion 116 and the first electrode 114 can have the same pattern that the stripe area can extend to the dotted-line area as shown in FIG. 1B, therefore causing the first electrode 114 block all downward current from the first electrode 114.

The first electrode 114 can be located on both the first portion 110a and the second portion 110b. Preferably, more than 10% of the area of the first electrode 114 overlaps the second portion 110b. As indicated from top view, the first electrode 114 protrudes from a first side 111 of the first portion 110a wherein a boundary side 121 of the light-emitting device 100 is opposite to the first side 111. In the embodiment, the boundary side 121 can be one side of the substrate 102. It can be seen that the shortest distance d from the first electrode 114 to the boundary side 121 is shorter than the shortest distance e between the first side 111 and the boundary side 121. In other words, the first electrode 114 is closer to the boundary side 121 comparing with the first side 111. In addition, a transparent conductive layer 113 such as metal oxide can be formed between the upper semiconductor layer 108 and the first electrode 114, and the current blocking portion 116 can be formed between the first electrode 114 and the second portion 110b, in particular, the current blocking portion 116 can be formed on the upper semiconductor layer 108 and covered by the transparent conductive layer 113. An extension electrode 114a extending from the first electrode 114 can be formed on the upper semiconductor layer 108 and/or the transparent conductive layer 113. In the embodiment, the area of the first electrode 114 over the first portion 110a is larger than that over the second portion 110b so that centroid C of the first electrode 114 is located in the first portion 110a.

In a conventional LED device, the current is not easily spread to the whole semiconductor layer, especially the edge regions. Extending the electrode to the edge of the semiconductor layer can be a way for spreading the current. However, the extension of the electrode absorbs the light of the LED device, therefore the benefits of current-spreading are not obvious. The LED device disclosed in the embodiments of the present application includes a smaller light-emitting area comparing with the conventional LED device so the current can be much concentrated and the optoelectronic efficiency of the light-emitting structure can be raised accordingly. Furthermore, the first electrode does not completely on the first portion 110a having the active layer thereunder so that absorption or blocking of the light emitted from the active layer can be reduced.

Referring to FIG. 1C, the first electrode 114 has larger area on the second portion 110b by enlarge the current blocking portion 116, and the centroid C of the first electrode 114 can be closer to the second portion 110b. The light-emitting structure 110 has a first side 111 and a second side 115 opposite to the first side 111, and the first electrode 114 and the second electrode 112 are near the first side 111 and second side 115 respectively, and a first direction f₁ from the first side 111 to second side 115 can be defined. The second electrode 112 has a length “a” along the first direction f₁ and a fourth side 112a closest to the second side 115, and a distance “c” along the first direction f₁ and between the second side 115 and the fourth side 112a can be defined. The first portion 110a further has a third side 117 located between the first side 111 and the second side 115, and a distance “b” along the first direction f₁ and between the second side 115 and the third side 117 can be defined. In the embodiment, the arrangement of the second electrode 112 and the first portion 110a can satisfy the following equation: b>c+0.5a, and in another layout of the embodiment as shown in FIG. 1D, less than 50% of the circumference of the second electrode 112 is surrounded by the first portion 110a.

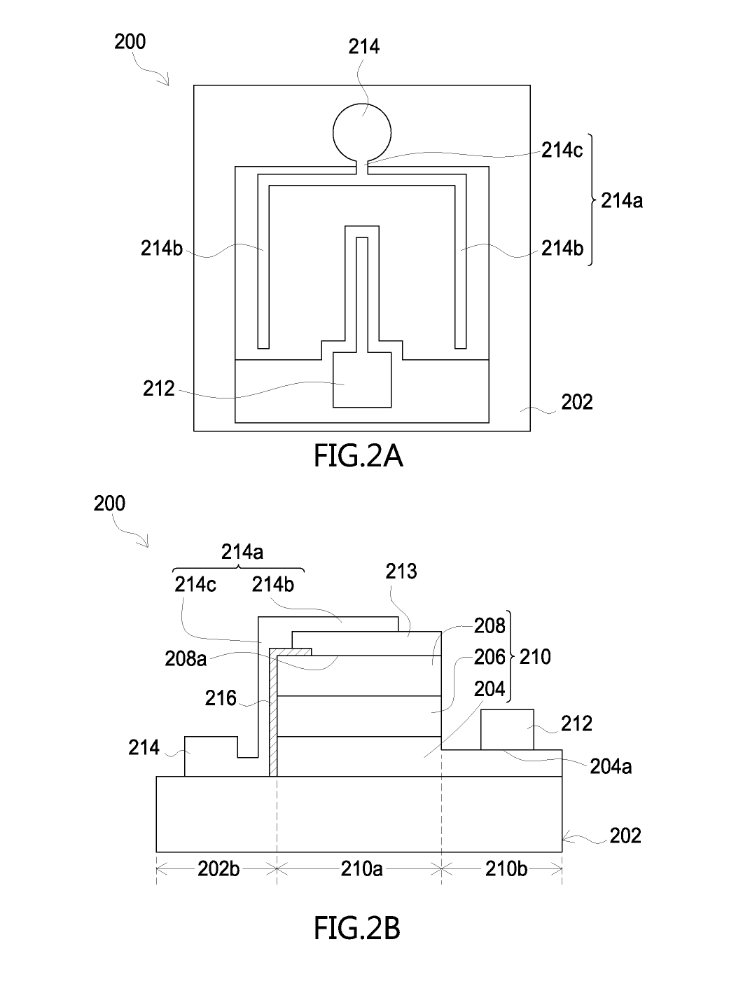

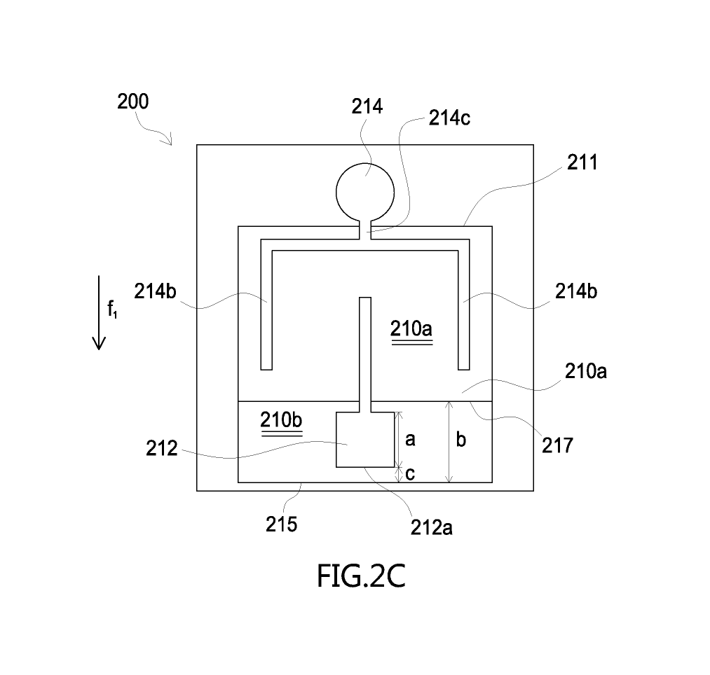

Referring to FIGS. 2A and 2B, a light-emitting device 200 in accordance with a second embodiment of the present application is disclosed. A light-emitting device 200 includes: a substrate 202, for example, an insulative and single-crystalline substrate, and in the embodiment the substrate 202 can be Sapphire; a light-emitting structure 210 formed on the substrate 202 including a lower semiconductor layer 204, an active layer 206 and an upper semiconductor layer 208; a first electrode 214 electrically connected to the upper semiconductor layer 208; and a second electrode 212 formed on the lower semiconductor layer 204. There are two portions defined in the light-emitting structure 210: a first portion 210a having a first top face 208a and a second portion 210b where no optoelectronic conversion occurs therein, having a second top face 204a lower than the first top face 208a. The first portion 210a includes part of the upper semiconductor layer 208 having the first top face 208a, the active layer 206, and the lower semiconductor layer 204. The second portion 210b including part of the lower semiconductor layer 204 having the second top face 204a. A transparent conductive layer 213 such as metal oxide can be formed on the upper semiconductor layer 208.

The substrate 202 can include an exposed region 202b other than the area having the light-emitting structure 210 disposed thereon. To be more specific, the exposed region 202b can surround the area having the light-emitting structure 210 disposed thereon. The ratio of the area of the first portion 210a to the area of the substrate 202 can be 0.5 to 0.8. The difference between the second embodiment and the first embodiment is that the entire first electrode 214 is outside the first portion 210a, and the first electrode 214 is over the exposed region 202b of the substrate 202. An extension electrode 214a can be formed to spread current by forming a finger 214b over the upper semiconductor layer 208, and a bridge 214c formed along the side surface of the light-emitting structure 210 to connect the first electrode 214 to the finger 214b. An insulating structure 216 can be formed between the bridge 214c and the side surface of the light-emitting structure 210.

Referring to FIG. 2C and FIG. 2B, the first portion 210a can be further shrunk comparing with what is disclosed in the first embodiment, and the electrical efficiency of light-emitting device 200 can be enhanced accordingly. The light-emitting structure 210 can have a first side 211 and a second side 215 opposite to the first side 211, and the first electrode 214 and the second electrode 212 are near the first side 211 and second side 215 respectively. A first direction f₁ from the first side 211 to second side 215 can be defined. The second electrode 212 has a length “a” along the first direction f₁ and a fourth side 212a closest to the second side 215, and a distance “c” between the second side 215 and the fourth side 212a can be defined. The first portion 210a further has a third side 217 located between the first side 211 and the second side 215, and a distance “b” along the first direction f₁ and between the second side 215 and the third side 217 can be defined. In the embodiment, the arrangement of second electrode 212 and the first portion 210a can satisfy the following equation: b≧c+a. The layout can be also applied to the first embodiment or other embodiments of the present application.

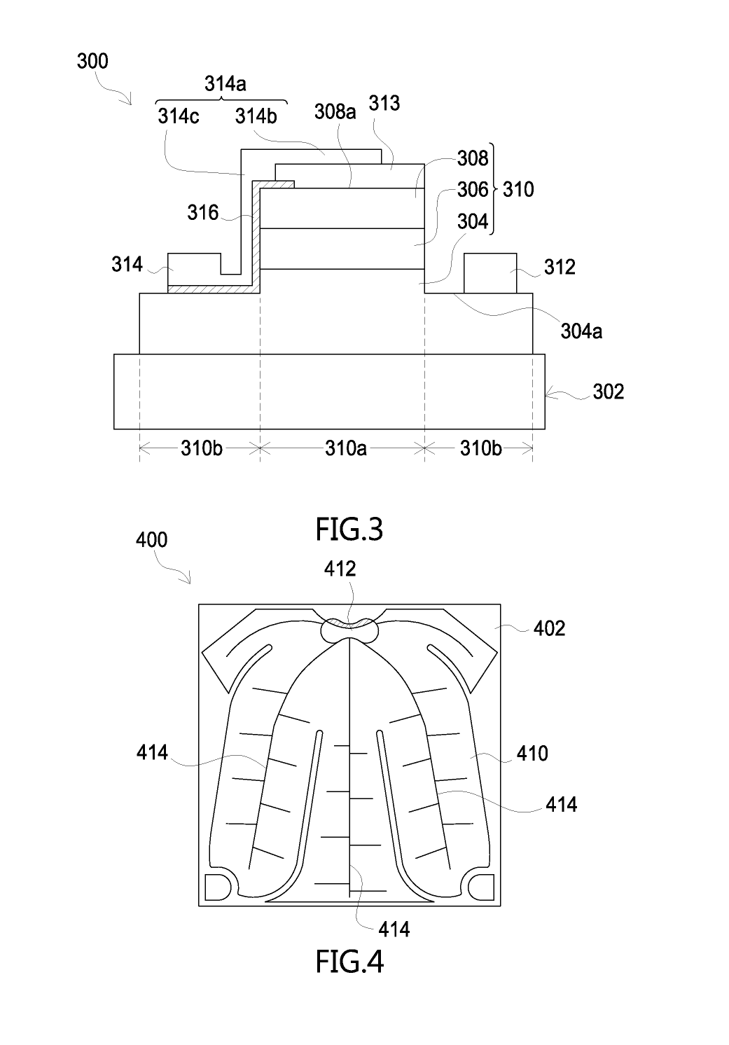

Referring to FIG. 3, a light-emitting device 300 in accordance with a third embodiment of the present application is disclosed. A light-emitting device 300 includes: a substrate 302, for example, an insulative and single-crystalline substrate, and in the embodiment the substrate 302 can be Sapphire; a light-emitting structure 310 formed on the substrate 302, including a lower semiconductor layer 304, an active layer 306, and an upper semiconductor layer 308; a first electrode 314 electrically connected to the upper semiconductor layer 308; and a second electrode 312 formed on the lower semiconductor layer 304. There are two portions defined in the light-emitting structure 310: a first portion 310a having a first top face 308a and a second portion 310b where no optoelectronic conversion occurs therein. The second portion 310b has a second top face 304a lower than the first top face 308a. The first portion 310a includes the upper semiconductor layer 308 having part of the first top face 308a, the active layer 306, and the lower semiconductor layer 304. The second portion 310b includes part of the lower semiconductor layer 304 having the second top face 304a. A transparent conductive layer 313 such as metal oxide can be formed between the upper semiconductor layer 308 and the first electrode 314.

Similar to the second embodiment, the entire first electrode 314 is located outside the first portion 310a. In the embodiment, the first electrode 314 is directly over the second portion 310b having part of the lower semiconductor layer 304. An extension electrode 314a includes a finger 314b over the upper semiconductor layer 308, and a bridge 314c formed along the side surface of the light-emitting structure 310 to connect the first electrode 314 to the finger 314b. An insulating structure 316 can be formed between the first electrode 314 and the second portion 310b, and between the bridge 314c and the side surface of the light-emitting structure 310.

Referring to FIG. 4, a light-emitting device 400 in accordance with a forth embodiment of the present application is disclosed. The light-emitting device 400 includes a substrate 402 and a first portion 410 formed on the substrate 402 by epitaxial growth. An electrode 412 and a plurality of extension electrodes 414 extended from the electrode 412 are on the first portion 410. The area of the first portion 410 is smaller than that of the substrate 402, and the shape of the first portion 410 can correspond to the distribution of the extension electrodes 414 approximately.

Each of the light-emitting structures of the aforesaid embodiments can be formed in an MOCVD chamber and composed of materials such as the series of aluminum gallium indium phosphide (AlGaInP), the series of aluminum gallium indium nitride (AlGaInN), and/or the series of zinc oxide (ZnO). The active layer can be configured as a single heterostructure (SH), a double heterostructure (DH), a double-side double heterostructure (DDH), or a multi-quantum well (MQW) structure.

Although the present application has been explained above, it is not the limitation of the range, the sequence in practice, the material in practice, or the method in practice. Any modification or decoration for present application is not detached from the spirit and the range of such.

What is claimed is:

1. A light-emitting device, comprising:
a substrate;
a light-emitting structure formed on the substrate and comprising a first portion and a second portion where no optoelectronic conversion occurs therein; and
a first electrode located on both the first portion and the second portion.

2. The light-emitting device according to claim 1, wherein the first portion has a first top surface and the second portion has a second top face lower than the first top surface.

3. The light-emitting device according to claim 2, wherein the first portion comprises a lower semiconductor layer, an active layer on the lower semiconductor layer, and an upper semiconductor layer having the first top surface on the active layer; and the second portion comprises the lower semiconductor layer having the second top surface.

4. The light-emitting device according to claim 3, further comprising a current blocking portion between a part of the first electrode and the second portion, wherein the area of the current blocking portion is smaller than that of the first electrode.

5. The light-emitting device according to claim 4, further comprising a transparent conductive layer between the upper semiconductor layer and the first electrode, and the current blocking portion is formed on the upper semiconductor layer and covered by the transparent conductive layer.

6. The light-emitting device according to claim 1, wherein the ratio of the area of the first portion to the area of the substrate is 0.5 to 0.8.

7. The light-emitting device according to claim 1, wherein more than 10% of the area of the first electrode overlaps the second portion.

8. The light-emitting device according to claim 1, wherein the light-emitting device comprises a boundary side, the first portion comprises a first side opposite to the boundary side, and the first electrode protrudes from a first side of the first portion and is closer to the boundary side than the first side.

9. The light-emitting device according to claim 1, wherein the substrate comprises an exposed region surrounding the region where the light-emitting structure is dispose thereon.

10. The light-emitting device according to claim 1, further comprising a second electrode on the second portion, wherein the light-emitting structure has a first side near the first electrode and a second side opposite to the first side and near the second electrode, and the second electrode has a length a along a first direction from the first side to the second side and a fourth side closest to the second side, and between the second side and the fourth side has a distance c, and the first portion has a third side between the first side and the second side, and along the first direction a distance b is between the second side and the third side, and the arrangement of the second electrode and the first portion satisfies the following equation: b>c+0.5a.

11. The light-emitting device according to claim 1, further comprising a second electrode on the second portion, wherein less than 50% of the circumference of the second electrode is surrounded by the first portion.

12. The light-emitting device according to claim 1, further comprising a second electrode on the second portion, wherein the light-emitting structure has a first side near the first electrode and a second side opposite to the first side and near the second electrode, and the second electrode has a length a along a first direction from the first side to the second side and a fourth side closest to the second side, and between the second side and the fourth side has a distance c, and the first portion has a third side between the first side and the second side, and along the first direction a distance b is between the second side and the third side, and the arrangement of the second electrode and the first portion satisfies the following equation: b≧c+a.

13. A light-emitting device, comprising:
a single-crystalline substrate;
a light-emitting structure formed on the substrate and comprising a first portion and a second portion, wherein the first portion comprises part of a lower semiconductor layer, an active layer on the lower semiconductor layer, and an upper semiconductor layer on the active layer, and no optoelectronic conversion occurs in the second portion; and
a first electrode electrically connected to the upper semiconductor layer and entirely located outside the first portion.

14. The light-emitting device according to claim 13, wherein the substrate is insulative and comprises an exposed region other than the region where the light-emitting structure is disposed on, and the first electrode is on the exposed region.

15. The light-emitting device according to claim 13, further comprising an extension electrode comprising a finger over the light-emitting structure and a bridge formed along the side surface of the light-emitting structure to connect the first electrode to the finger.

16. The light-emitting device according to claim 15, further comprising an insulating structure formed between the bridge and the side surface of the light-emitting structure.

17. The light-emitting device according to claim 13, wherein the second portion comprises part of the lower semiconductor layer, and the first electrode is on the second portion, and an insulating structure is formed between the first electrode and the second portion.

18. The light-emitting device according to claim 17, further comprising an extension electrode comprising a finger over the light-emitting structure and a bridge formed along the side surface of the light-emitting structure to connect the first electrode to the finger, and the insulating structure is further formed between the bridge and the side surface of the light-emitting structure.

19. The light-emitting device according to claim 13, wherein the first electrode is on the upper semiconductor layer, and a current blocking portion having the same pattern with that of the first electrode is directly under the first electrode and above the upper semiconductor layer.

20. The light-emitting device according to claim 19, further comprising a transparent conductive layer formed between the upper semiconductor layer and the first electrode, and the current blocking portion is formed on the upper semiconductor layer and covered by the transparent conductive layer.
